(19) United States
(12) Patent Application Publication
(10) Pub. No.: US 2026/0007036 A1
(43) Pub. Date: Jan. 1, 2026

(54) Organic Light-Emitting Diode Display with Non-Planar Anodes

(71) Applicant: Apple Inc., Cupertino, CA (US)

(72) Inventors: Yue Qu, Redwood City, CA (US); Chih-An Huang, Yilan (TW); Chih-Lei Chen, Tai Chung (TW); Chuan-Jung Lin, Zhubei (TW); Chun-Kai Chang, Zhubei (TW); David A. Doyle, Needham, MA (US); Jianhong Lin, Taoyuan City (TW); Jung Yen Huang, Taoyuan City (TW); Kwang Ohk Cheon, San Jose, CA (US); Li-An Liu, Keelung (TW); Min-Ling Lin, New Taipei City (TW); Pei-Ling Lin, New Taipei City (TW); Po-Yu Lin, New Taipei City (TW); Rui Liu, Los Altos, CA (US); Wendi Chang, Sunnyvale, CA (US); Yifan Zhang, Palo Alto, CA (US); Yin-Ting Chen, Hsinchu City (TW); Yung Da Lai, Hsinchu City (TW); Yung-Sheng Tsai, New Taipei City (TW); Edward Lin, San Jose, CA (US); Po-Chun Yeh, Sunnyvale, CA (US); Akanksha Gupta, Fremont, CA (US); Jiun-Jye Chang, Cupertino, CA (US); Shinya Ono, Santa Clara, CA (US); Martijn Kuik, San Jose, CA (US); Kan Ding, Santa Clara, CA (US); Chin-Wei Lin, San Jose, CA (US); Danyong Lu, San Diego, CA (US); Yun Liu, Sunnyvale, CA (US); Chia-Hsin Lin, Kaohsiung City (TW); Cheng Min Hu, Hsinchu City (TW); Yu-Hsien Lin, Keelung (TW); Abhijeet S. Bagal, Sunnyvale, CA (US); Ching-Sang Chuang, Sunnyvale, CA (US)

(21) Appl. No.: 19/200,232

(22) Filed: May 6, 2025

Related U.S. Application Data
(60) Provisional application No. 63/664,601, filed on Jun. 26, 2024.

(51) Int. Cl. H10K 59/80; H10K 59/122; H10K 102/00

(52) U.S. Cl. CPC H10K 59/80515; H10K 59/122; H10K 2102/351

(57) ABSTRACT

A display may include organic light-emitting diode (OLED) pixels. Each pixel may include OLED layers that are interposed between an anode and a cathode. The anode may be formed on a substrate. A layer of material that defines a plurality of bumps or recesses may be formed on the substrate. The anode may conform to the layer of material and may have a plurality of curved portions that are aligned with the bumps or recesses. The anode may have a side mirror portion that conforms to a tapered surface. A black pixel definition layer may be positioned above or below the side mirror portion of the anode. A pixel may include a pixel definition layer that defines multiple light-emitting apertures that overlap a single anode. The multiple light-emitting apertures may have circular, square, or non-square rectangular footprints.

This application claims the benefit of U.S. provisional patent application No. 63/664,601, filed Jun. 26, 2024, which is hereby incorporated by reference herein in its entirety.

### BACKGROUND

This relates generally to electronic devices, and, more particularly, to electronic devices with displays.

Electronic devices often include displays. For example, an electronic device may have an organic light-emitting diode (OLED) display based on organic light-emitting diode pixels. Each organic light-emitting diode pixel may have an anode and a cathode. The display may include an active area and an inactive area.

It is within this context that the embodiments herein arise.

### SUMMARY

An electronic device may include a display that includes an array of pixels. A pixel in the array of pixels may include a substrate, a layer of material on the substrate that defines a plurality of features, an anode that conforms to the plurality of features, the anode having a plurality of curved portions that is aligned with the plurality of features, organic light-emitting diode layers that overlap the anode, and a cathode that overlaps the organic light-emitting diode layers.

An electronic device may include a display that includes an array of pixels. A pixel in the array of pixels may include a substrate, an anode with a footprint, organic light-emitting diode layers that overlap the anode, a cathode that overlaps the organic light-emitting diode layers, and a pixel definition layer that defines multiple light-emitting apertures for the pixel. Each one of the multiple light-emitting apertures may overlap the footprint and the anode may overlap the pixel definition layer between the multiple light-emitting apertures.

An electronic device may include a display that includes an array of pixels. A pixel in the array of pixels may include a substrate, an anode that has a first portion on the substrate, a second portion, and a conductive via between the first and second portions, a layer of material on the first portion of the anode that defines a plurality of structures, an additional material that is interposed between the first and second portions of the anode and that conforms to the plurality of structures, organic light-emitting diode layers that overlap the second portion of the anode, and a cathode that overlaps the organic light-emitting diode layers. The first portion may be more reflective than the second portion, the plurality of structures may be interposed between the first and second portions of the anode, and the additional material may have a different refractive index than the layer of material.

### BRIEF DESCRIPTION OF THE DRAWINGS

FIG. 1 is a schematic diagram of an illustrative electronic device having a display in accordance with some embodiments.

FIG. 2 is a schematic diagram of an illustrative display in accordance with some embodiments.

FIG. 3 is a diagram of an illustrative pixel circuit in accordance with some embodiments.

FIG. 4 is a cross-sectional side view of an illustrative organic light-emitting diode display showing different layers of the organic light-emitting diodes in accordance with some embodiments.

FIG. 5 is a cross-sectional side view of an illustrative display pixel having a non-planar anode that conforms to a plurality of bumps in accordance with some embodiments.

FIG. 6 is a cross-sectional side view of an illustrative display pixel having a non-planar anode with a portion that forms a side mirror in accordance with some embodiments.

FIG. 7 is a cross-sectional side view of an illustrative display pixel having a non-planar anode that conforms to a plurality of recesses in accordance with some embodiments.

FIG. 8 is a cross-sectional side view of an illustrative display pixel having a structured layer between first and second parallel anode portions in accordance with some embodiments.

FIG. 9 is a cross-sectional side view of an illustrative display pixel having a structured layer on top of an anode portion in accordance with some embodiments.

FIGS. 10A-10F are top views of illustrative display pixels showing various layouts for features that overlap an anode in accordance with some embodiments.

FIG. 11 is a cross-sectional side view of an illustrative display pixel having a pixel definition layer that defines multiple light-emitting apertures in accordance with some embodiments.

FIGS. 12A-12C are top views of illustrative displays showing various layouts for pixels with multiple light-emitting apertures in accordance with some embodiments.

FIG. 13 is a cross-sectional side view of an illustrative display pixel with a black pixel definition layer that is positioned above a side mirror anode metal portion in accordance with some embodiments.

FIG. 14 is a cross-sectional side view of an illustrative display pixel with a black pixel definition layer that is positioned below a side mirror anode metal portion in accordance with some embodiments.

FIG. 15 is a cross-sectional side view of an illustrative display pixel with a black pixel definition layer that is positioned below a side mirror anode metal portion and a transparent pixel definition layer in accordance with some embodiments.

FIG. 16A is a cross-sectional side view of an illustrative display pixel with a cutting structure and a pixel definition layer that overlaps a sloped portion of the cutting structure in accordance with some embodiments.

FIG. 16B is a cross-sectional side view of the illustrative cutting structure of FIG. 16A in accordance with some embodiments.

FIG. 17 is a cross-sectional side view of an illustrative display pixel with a cutting structure and OLED layers that overlap a sloped portion of the cutting structure in accordance with some embodiments.

FIG. 18 is a cross-sectional side view of an illustrative display pixel having a non-planar anode that conforms to a plurality of multilayer bumps in accordance with some embodiments.

### DETAILED DESCRIPTION

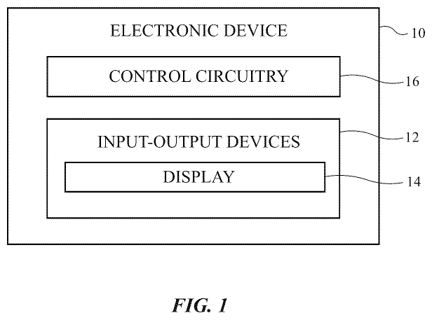

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user. As examples, electronic device 10 may be an augmented reality (AR) headset and/or virtual reality (VR) headset.

As shown in FIG. 1, electronic device 10 may include control circuitry 16 for supporting the operation of device 10. The control circuitry may include storage such as hard disk drive storage, nonvolatile memory (e.g., flash memory or other electrically-programmable-read-only memory configured to form a solid state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

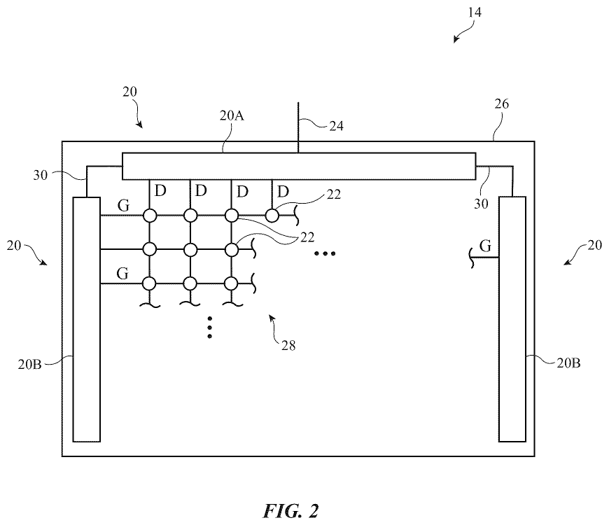

FIG. 2 is a diagram of an illustrative display. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, silicon layers, composite films that include polymer and inorganic materials, metallic foils, etc.

Display 14 may have an array of pixels 22 for displaying images for a user such as pixel array 28. Pixels 22 in array 28 may be arranged in rows and columns. The edges of array 28 may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Display 14 may include pixels 22 of different colors. As an example, display 14 may include red pixels, green pixels, and blue pixels.

Display driver circuitry 20 may be used to control the operation of pixels 28. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 as shown in FIG. 2.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply corresponding image data to data lines D while issuing control signals to supporting display driver circuitry such as gate driver circuitry 20B over signal paths 30. With the illustrative arrangement of FIG. 2, data lines D run vertically through display 14 and are associated with respective columns of pixels 22.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally through display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.).

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel 22 may have a light-emitting diode and circuitry (e.g., thin-film circuitry on substrate 26) that responds to the control and data signals from display driver circuitry 20.

Gate driver circuitry 20B may include blocks of gate driver circuitry such as gate driver row blocks. Each gate driver row block may include circuitry such output buffers and other output driver circuitry, register circuits (e.g., registers that can be chained together to form a shift register), and signal lines, power lines, and other interconnects. Each gate driver row block may supply one or more gate signals to one or more respective gate lines in a corresponding row of the pixels of the array of pixels in the active area of display 14.

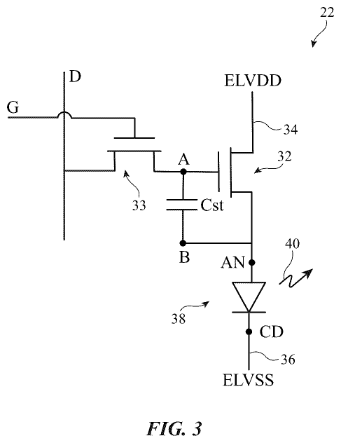

A schematic diagram of an illustrative pixel circuit of the type that may be used for each pixel 22 in array 28 is shown in FIG. 3. As shown in FIG. 3, display pixel 22 may include light-emitting diode 38. A positive power supply voltage ELVDD may be supplied to positive power supply terminal 34 and a negative (ground) power supply voltage ELVSS may be supplied to ground power supply terminal 36. Diode 38 has an anode (terminal AN) and a cathode (terminal CD). The state of drive transistor 32 controls the amount of current flowing through diode 38 and therefore the amount of emitted light 40 from display pixel 22. Cathode CD of diode 38 is coupled to ground terminal 36, so cathode terminal CD of diode 38 may sometimes be referred to as the ground terminal for diode 38.

To ensure that transistor 38 is held in a desired state between successive frames of data, display pixel 22 may include a storage capacitor such as storage capacitor Cst. The voltage on storage capacitor Cst is applied to the gate of transistor 32 at node A to control transistor 32. Data can be loaded into storage capacitor Cst using one or more switching transistors such as switching transistor 33. When switching transistor 33 is off, data line D is isolated from storage capacitor Cst and the gate voltage on terminal A is equal to the data value stored in storage capacitor Cst (i.e., the data value from the previous frame of display data being displayed on display 14). When gate line G (sometimes referred to as a scan line) in the row associated with display pixel 22 is asserted, switching transistor 33 will be turned on and a new data signal on data line D will be loaded into storage capacitor Cst. The new signal on capacitor Cst is applied to the gate of transistor 32 at node A, thereby adjusting the state of transistor 32 and adjusting the corresponding amount of light 40 that is emitted by light-emitting diode 38. If desired, the circuitry for controlling the operation of light-emitting diodes for display pixels in display 14 (e.g., transistors, capacitors, etc. in display pixel circuits such as the display pixel circuit of FIG. 3) may be formed using other configurations (e.g., configurations that include circuitry for compensating for threshold voltage variations in drive transistor 32, etc.). The display pixel circuit of FIG. 3 is merely illustrative.

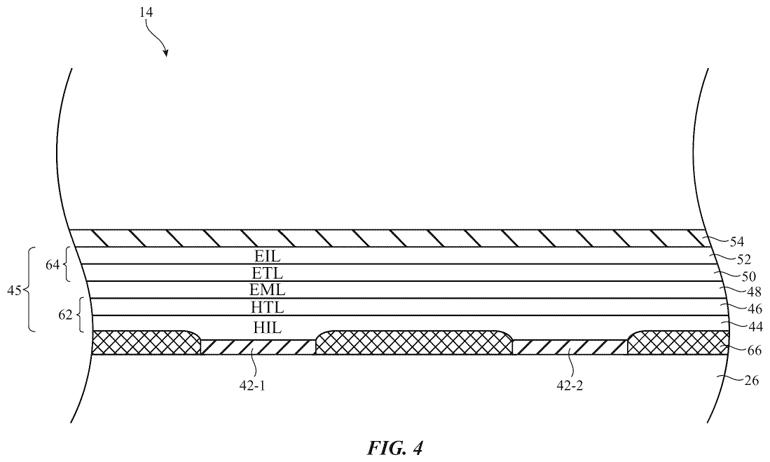

FIG. 4 is a cross-sectional side view of an illustrative display with organic light-emitting diode display pixels. As shown, display 14 may include a substrate 26. Substrate 26 may be formed from glass, plastic, polymer, silicon, or any other desired material. Anodes such as anodes 42-1 and 42-2 may be formed on the substrate. Anodes 42-1 and 42-2 may be formed from conductive material and may be covered by OLED layers 45 and cathode 54. OLED layers 45 may include one or more layers for forming an organic light-emitting diode. For example, layers 45 may include one or more of a hole-injection layer (HIL), a hole-transport layer (HTL), an emissive layer (EML), an electron-transport layer (ETL), and an electronic-injection layer (EIL). Cathode 54 may be a conductive layer formed on the OLED layers 45. Cathode layer 54 may form a common cathode terminal (see, e.g., cathode terminal CD of FIG. 3) for all diodes in display 14. Cathode layer 54 may be formed from a transparent conductive material (e.g., indium tin oxide, a metal layer(s) that is sufficiently thin to be transparent, a combination of a thin metal and indium tin oxide, etc.). Each anode in display 14 may be independently controlled, so that each diode in display 14 can be independently controlled. This allows each pixel 22 to produce an independently controlled amount of light. Anodes 42 may sometimes be referred to as electrodes or pixel electrodes. Cathode 54 may sometimes be referred to as a common electrode.

Display 14 may optionally include a pixel definition layer (PDL) 66. The pixel definition layer may be formed from a dielectric material and may be interposed between adjacent anodes of the display. The pixel definition layer may have openings in which the anodes are formed, thereby defining the area of each pixel.

As shown in FIG. 4, OLED layers 45 (sometimes referred to as an organic stack-up, an organic stack, or an organic light-emitting diode (OLED) stack) may include a hole injection layer (HIL) 44, a hole transport layer (HTL) 46, an emissive layer (EML) 48, an electron transport layer (ETL) 50, and an electron injection layer (EIL) 52 interposed between anodes 42 and cathode 54. The hole injection layer and hole transport layer may collectively be referred to as a hole layer (i.e., hole layer 62). The electron transport layer and the electron injection layer may collectively be referred to as an electron layer (i.e., electron layer 64). Emissive layer 48 may include organic electroluminescent material. As shown, hole layer 62 and electron layer 64 may be blanket (common) layers that cover the entire array.

The examples of layers included between the anodes 42 and the cathode 54 in FIG. 4 are merely illustrative. If desired, additional layers may be included between anodes 42 and cathode 54 (i.e., an electron blocking layer, a charge generation layer, a hole blocking layer, etc.), such as in a tandem organic light-emitting diode.

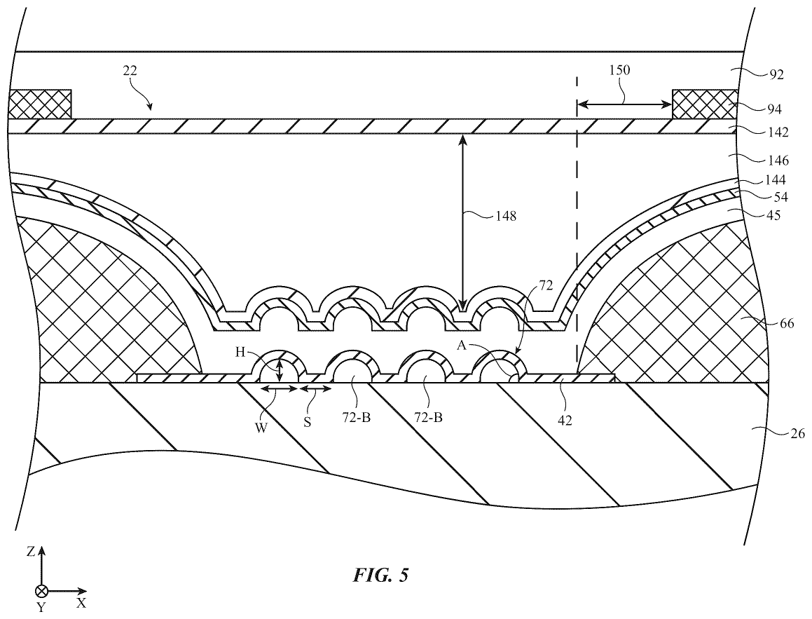

FIG. 5 is a cross-sectional side view of an illustrative display pixel having an anode with one or more surface features. As previously mentioned, substrate 26 may include glass layers, polymer layers, silicon layers, composite films that include polymer and inorganic materials, metallic foils, etc. In one example, shown in FIG. 5, substrate 26 in FIG. 5 is a planarization layer. The planarization layer 26 has a planar upper surface. In FIG. 4, anodes 42 are formed directly on the planar upper surface of the planarization layer and therefore anodes 42 are planar. In FIG. 5, a layer 72 defining one or more bumps 72-B is formed on the planar upper surface of the planarization layer and anode 42 is formed over the bumps. Anode 42 conforms to the bumps and therefore has multiple curved portions (each curved portion overlapping a respective bump). Anode 42 may be referred to as a curved anode or non-planar anode.

Including bumps 72-B as in FIG. 5 may improve the large viewing angle performance of display pixel 22 in FIG. 5 compared to the display pixels of FIG. 4 (where the anode is planar). Display pixel 22 may have higher brightness/efficiency at off-axis viewing angles in FIG. 5 than in FIG. 4.

The bumps 72-B (sometimes referred to as anode bumps 72-B, discrete bumps 72-B, dielectric bumps 72-B, etc.) may be formed from a metal material, an organic dielectric material, an inorganic dielectric material, etc. The bumps may have curved cross-sectional shapes (as in FIG. 5) or other desired cross-sectional shapes.

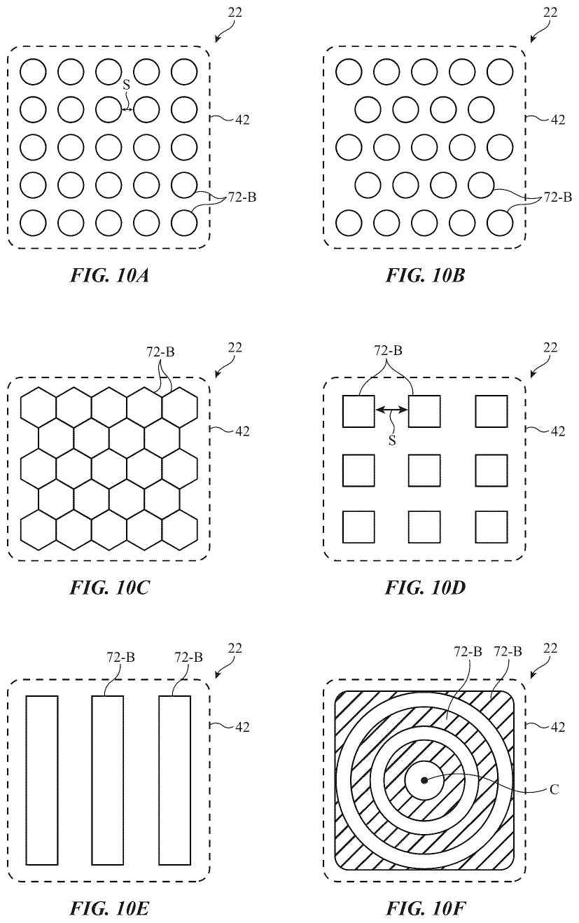

Each anode may overlap any desired number of bumps 72-B (e.g., more than 3, more than 5, more than 8, more than 12, more than 20, more than 30, more than 50, more than 100, more than 200, etc.). The bumps may be arranged in a regular grid, a checkerboard pattern, without any intervening gaps, etc. (as will be shown and described in more detail in FIGS. 10A-10F).

Each bump may have a width W, height H, and a taper angle A (e.g., the angle at which the bump meets substrate 26). Width W may be less than 5 microns, less than 3 microns, less than 2 microns, less than 1 micron, less than 500 nanometers, less than 300 nanometers, less than 200 nanometers, less than 100 nanometers, less than 50 nanometers, greater than 50 nanometers, greater than 500 nanometers, greater than 1 micron, greater than 2 microns, etc. Height H may be less than 5 microns, less than 3 microns, less than 2 microns, less than 1 micron, less than 500 nanometers, less than 300 nanometers, less than 200 nanometers, less than 100 nanometers, less than 50 nanometers, greater than 50 nanometers, greater than 500 nanometers, greater than 1 micron, greater than 2 microns, etc. Taper angle A may be less than 80 degrees, less than 70 degrees, less than 60 degrees, less than 50 degrees, less than 40 degrees, less than 30 degrees, less than 20 degrees, greater than 20 degrees, greater than 40 degrees, greater than 60 degrees, greater than 70 degrees, between 10 degrees and 80 degrees, etc.

Adjacent bumps 72-B may be separated by a space S having a magnitude that is less than 5 microns, less than 3 microns, less than 2 microns, less than 1 micron, less than 500 nanometers, less than 300 nanometers, less than 200 nanometers, less than 100 nanometers, less than 50 nanometers, greater than 50 nanometers, greater than 500 nanometers, greater than 1 micron, greater than 2 microns, etc.

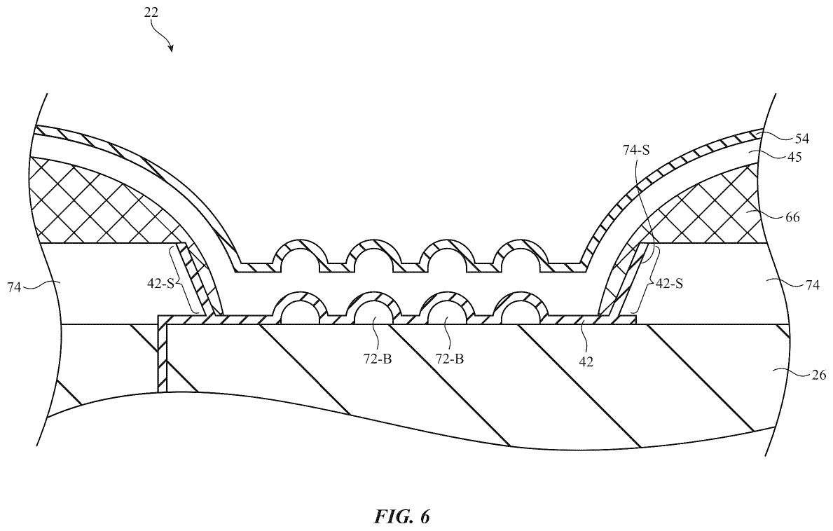

In FIG. 5, pixel definition layer 66 overlaps the edges of anode 42 and defines a light-emitting opening for pixel 22. OLED layers 45 are formed over anode 42 (with curved portions caused by bumps 72-B) and pixel definition layer 66. Cathode 54 overlaps OLED layers 45. This arrangement is merely illustrative. In another possible arrangement, shown in FIG. 6, an additional layer 74 is formed between substrate 26 and pixel definition layer 66. Additional layer 74 may sometimes be referred to as a dielectric layer, planarization layer, etc. Layer 74 defines a surface for anode metal portions 42-S, which are used to increase efficiency/luminance for display pixel 22 at large viewing angles.

FIG. 5 further shows how display pixel 22 may include a color filter element 92 and an opaque masking layer 94. One or more layers may be interposed between cathode 54 and color filter element 92.

A first passivation layer 144 is formed over cathode 54. Passivation layer 144 may form a moisture blocking layer that prevents moisture from penetrating to reach OLED layers 45. Passivation layer 144 may be formed from, for example, an inorganic material. The surface topology of the OLED stack and processing restraints (to prevent damaging the OLED stack) may result in passivation layer 144 not forming a total moisture seal for OLED layers 45. Accordingly, a planarization layer 146 (sometimes referred to as inkjet layer 146) may be formed over passivation layer 144. Planarization layer 146 may be formed from an organic material that is deposited using inkjet printing. The planarization layer 146 may planarize the surface topology of the OLED layers, resulting in a planar upper surface for the planarization layer 146. An additional passivation layer 142 is then formed over the planarization layer 146. The additional passivation layer 142 may form a final moisture-block that prevents any moisture from penetrating to reach OLED layers 45.

The dimensions of planarization layer 146 may be selected to increase efficiency/luminance for display pixel 22 at large viewing angles. Planarization layer 146 has a maximum thickness 148. The maximum thickness 148 may be less than 5 microns, less than 3 microns, less than 2 microns, etc.

Opaque masking layer 94 forms a ring around pixel 22. The centermost edge of opaque masking layer 94 may be offset by a distance 150 (within a plane parallel to the upper surface of substrate 26, or the XY plane in FIG. 5) from the centermost edge of pixel definition layer 66. The magnitude of distance 150 may be selected to increase efficiency/luminance for display pixel 22 at large viewing angles. Distance 150 (around the entire periphery of pixel 22) may be greater than 5 microns, greater than 7 microns, greater than 10 microns, greater than 15 microns, etc.

As shown in FIG. 6, each dielectric layer 74 has an angled surface 74-S (sometimes referred to as tapered surface 74-S) that is adjacent to an edge of anode 42. Anode 42 has a portion 42-S that is formed on the angled surface 74-S. Anode 42 may be formed from reflective metal (e.g., having a reflectance that is greater than 60%, greater than 70%, greater than 80%, greater than 90%, greater than 95%, between 60% and 98%, etc.). The angled portions 42-S may therefore reflect light emitted by pixel 22 and improve the performance of pixel 22.

Angled surface 74-S may have any desired taper angle relative to the planar upper surface of substrate 26 (e.g., less than 80 degrees, less than 70 degrees, less than 60 degrees, less than 50 degrees, less than 40 degrees, less than 30 degrees, less than 20 degrees, greater than 20 degrees, greater than 40 degrees, greater than 60 degrees, greater than 70 degrees, between 10 degrees and 80 degrees, etc.).

Angled surface 74-S with conformal reflective anode portion 42-S may be referred to as an optical side mirror for pixel 22.

Layers 72 and 74 may optionally be formed from the same material (and during the same manufacturing step). Said another way, bumps 72-B and dielectric layer 74 may comprise different portions of a common layer (e.g., a common dielectric layer).

Layer 74 may have a central opening aligned with the light-emitting area of pixel 22. Accordingly, reflective anode portion 42-S may extend in a ring around the light-emitting area of pixel 22.

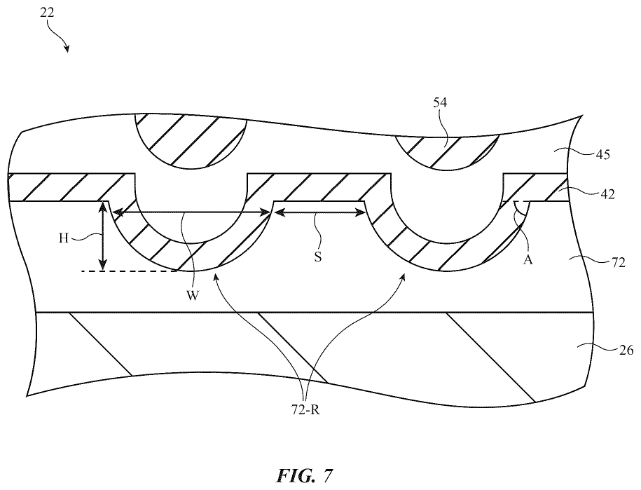

In the example of FIGS. 5 and 6, bumps 72-B have convex curved surfaces. In other words, the bumps are protrusions that extend in the positive Z-direction (e.g., the direction that light is emitted by pixels 22). This example is merely illustrative. Alternatively, as shown in FIG. 7, layer 72 may define recesses 72-R with concave curved surfaces that extend in the negative Z-direction. Both bumps 72-B and recesses 72-R may be referred to as feature or surface features.

Each recess 72-R may have a height H, width W, and taper angle A. Width W may be less than 5 microns, less than 3 microns, less than 2 microns, less than 1 micron, less than 500 nanometers, less than 300 nanometers, less than 200 nanometers, less than 100 nanometers, less than 50 nanometers, greater than 50 nanometers, greater than 500 nanometers, greater than 1 micron, greater than 2 microns, etc. Height H may be less than 5 microns, less than 3 microns, less than 2 microns, less than 1 micron, less than 500 nanometers, less than 300 nanometers, less than 200 nanometers, less than 100 nanometers, less than 50 nanometers, greater than 50 nanometers, greater than 500 nanometers, greater than 1 micron, greater than 2 microns, etc. Taper angle A may be less than 80 degrees, less than 70 degrees, less than 60 degrees, less than 50 degrees, less than 40 degrees, less than 30 degrees, less than 20 degrees, greater than 20 degrees, greater than 40 degrees, greater than 60 degrees, greater than 70 degrees, between 10 degrees and 80 degrees, etc.

Anode 42 conforms to the recesses and therefore has multiple curved portions (each curved portion overlapping a respective recess). The recesses may have curved cross-sectional shapes (as in FIG. 7) or other desired cross-sectional shapes. Each anode may overlap any desired number of recesses 72-R (e.g., more than 3, more than 5, more than 8, more than 12, more than 20, more than 30, more than 50, more than 100, more than 200, etc.). The recesses may be arranged in a regular grid, a checkerboard pattern, without any intervening gaps, etc. (as will be shown and described in more detail in FIGS. 10A-10F).

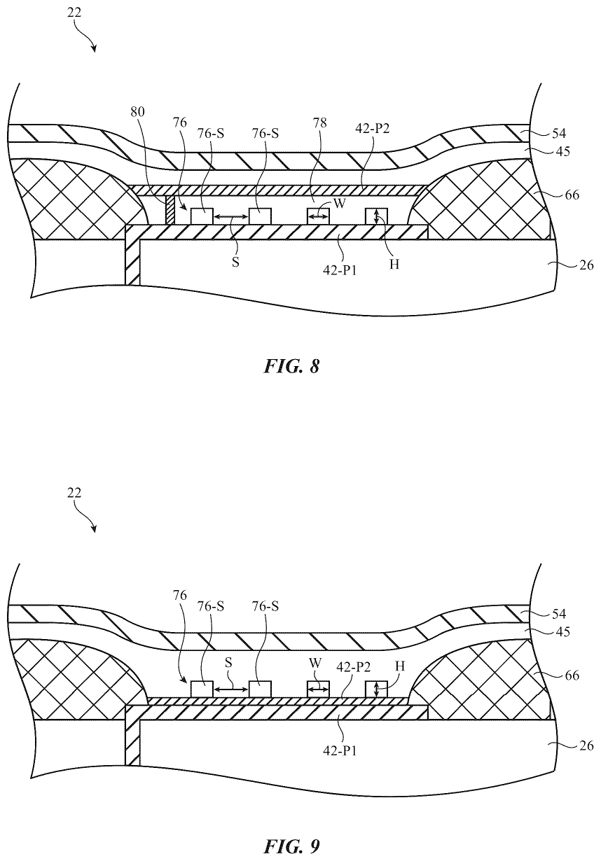

Another option to improve efficiency of pixel 22 (that may be included instead of or in addition to the anode surface features of FIGS. 5-7) is to incorporate an anode structure layer into display pixel 22. FIGS. 8 and 9 show examples of this type. As shown in FIG. 8, anode 42 may include a first anode portion 42-P1 and a second anode portion 42-P2. The first and second anode portions are planar and parallel. The first anode portion may be formed from a reflective material (e.g., having a reflectance that is greater than 60%, greater than 70%, greater than 80%, greater than 90%, greater than 95%, between 60% and 98%, etc.). In contrast, the second anode portion may be formed from a transparent material (e.g., having a transparency that is greater than 60%, greater than 70%, greater than 80%, greater than 90%, greater than 95%, between 60% and 99%, etc.). In other words, the first anode portion is more reflective than the second anode portion and the second anode portion is more transparent than the first anode portion. In one example, portion 42-P1 comprises silver and portion 42-P2 comprises indium tin oxide (ITO).

As shown in FIG. 8, there may be a conductive via 80 that electrically connects anode portions 42-P1 and 42-P2. Anode portions 42-P1 and 42-P2 are therefore shorted to a single anode voltage. Anode portion 42-P2 may directly contact OLED layers 45 and electrically functions as part of the anode. However, anode 42-P2 is optically transparent.

First and second materials 76 and 78 may be interposed between anode portions 42-P1 and 42-P2. First material 76 may sometimes be referred to as structured layer 76, anode structure layer 76, etc. Second material 78 may sometimes be referred to as conformal layer 78.

Structured layer 76 has a plurality of discrete structures 76-S that are formed on the upper surface of anode portion 42-P1. Conformal layer 78 conforms to the discrete structures and fills the gap between anode portions 42-P1 and 42-P2. The materials of layers 76 and 78 may have different refractive indices. The difference in refractive index between the materials of layers 76 and 78 may be at least 0.01, at least 0.05, at least 0.1, at least 0.2, at least 0.3, less than 0.5, less than 0.3, between 0.05 and 0.5, etc.

Conformal layer 78 may be formed from a transparent material (e.g., having a transparency that is greater than 60%, greater than 70%, greater than 80%, greater than 90%, greater than 95%, between 60% and 99%, etc.). Conformal layer 78 may be formed from a dielectric material. Structured layer 76 may comprise a dielectric material or a metal material (e.g., silver). Structured layer 76 may optionally be transparent.

The total thickness of the gap between the lower surface of anode portion 42-P2 and the upper surface of anode portion 42-P1 may be less than 5 microns, less than 3 microns, less than 2 microns, less than 1 micron, less than 500 nanometers, less than 300 nanometers, less than 200 nanometers, less than 100 nanometers, less than 50 nanometers, greater than 50 nanometers, greater than 500 nanometers, greater than 1 micron, greater than 2 microns, between 300 nanometers and 3 microns, etc.

The presence of structured layer 76 (with a refractive index that differs from conformal layer 78) in FIG. 8 may improve efficiency of display pixel 22.

The example in FIG. 8 of structured layer 76 being formed between anode portions 42-P1 and 42-P2 is merely illustrative. In another possible arrangement, shown in FIG. 9, anode 42 may include an anode portion 42-P2 that is formed directly on the upper surface of anode portion 42-P1. Structured layer 76 is formed directly on the upper surface of anode portion 42-P2. In this example, structured layer 76 may be formed from a transparent dielectric material (e.g., having a transparency that is greater than 60%, greater than 70%, greater than 80%, greater than 90%, greater than 95%, between 60% and 99%, etc.). OLED layers 45 may conform to structures 76-S of layer 76. There may be a refractive index difference between the material of layer 76 and OLED layers 45 that conform to structures 76-S. The difference in refractive index between the materials of layers 76 and 45 may be at least 0.01, at least 0.05, at least 0.1, at least 0.2, at least 0.3, less than 0.5, less than 0.3, between 0.05 and 0.5, etc.

In FIGS. 8 and 9, each structure 76-S has a rectangular cross-sectional profile. This example is merely illustrative. In general, each structure 76-S may have a cross-sectional profile of any desired shape.

In FIGS. 8 and 9, each discrete structure 76-S in structured layer 76 may have a width W and a height H. Width W may be less than 5 microns, less than 3 microns, less than 2 microns, less than 1 micron, less than 500 nanometers, less than 300 nanometers, less than 200 nanometers, less than 100 nanometers, less than 50 nanometers, greater than 50 nanometers, greater than 500 nanometers, greater than 1 micron, greater than 2 microns, between 50 nanometers and 1 micron, etc. Height H may be less than 5 microns, less than 3 microns, less than 2 microns, less than 1 micron, less than 500 nanometers, less than 300 nanometers, less than 200 nanometers, less than 100 nanometers, less than 50 nanometers, greater than 50 nanometers, greater than 500 nanometers, greater than 1 micron, greater than 2 microns, between 300 nanometers and 3 microns, between 50 nanometers and 1 micron, etc.

Adjacent structures in layer 76 may be separated by a space S having a magnitude that is less than 10 microns, less than 5 microns, less than 3 microns, less than 2 microns, less than 1 micron, less than 500 nanometers, less than 300 nanometers, less than 200 nanometers, less than 100 nanometers, less than 50 nanometers, greater than 50 nanometers, greater than 500 nanometers, greater than 1 micron, greater than 2 microns, etc.

FIGS. 10A-10F are top views of illustrative display pixels 22 showing illustrative arrangements for bumps 72-B. In the example of FIG. 10A, each bump 72-B has a circular footprint and the bumps are arranged in a regular grid of rows and columns. There is a space S between each adjacent bump in each row and column. In FIG. 10B, each bump 72-B again has a circular footprint. The bumps are also arranged in rows. However, each row is shifted relative to its preceding row to cause the grid of bumps to have zigzag columns. FIG. 10C shows an option where there is no space between adjacent bumps (e.g., S=0) and each bump has a hexagonal footprint. In the example of FIG. 10D, each bump 72-B has a square footprint and the bumps are arranged in a regular grid of rows and columns. There is a space S between each adjacent bump in each row and column. In the example of FIG. 10E, each bump 72-B has a rectangular footprint with an aspect ratio (e.g., a ratio of the longer dimension of the rectangle to the shorter dimension of the rectangle) that is greater than 2:1, greater than 3:1, greater than 4:1, greater than 5:1, greater than 10:1, etc. The bumps of FIG. 10E may be referred to as having strip-shaped footprints. In FIG. 10F, the bumps 72-B are formed in concentric rings around a center C of the pixel. Each bump in FIG. 10F has a ring-shaped footprint with a central opening that is aligned with center C. The diameter of the central opening is progressively larger for each bump.

In general, each bump may have any desired footprint (e.g., circular, square, non-square rectangular, hexagonal, etc.) and a single pixel may have any desired number of bumps in any desired regular or irregular grid. To mitigate periodicity that may cause diffraction artifacts, it may be desirable for the bumps to be randomly distributed across the footprint of the anode. The magnitude of the space S between adjacent bumps may vary (e.g., there may be at least 4 unique spaces between adjacent bumps, at least 10 unique spaces between adjacent bumps, at least 20 unique spaces between adjacent bumps, at least 30 unique spaces between adjacent bumps, etc.). The bumps may be arranged randomly instead of in rows and columns. The footprints of the bumps may also vary if desired (e.g., there may be bumps of at least 4 unique footprints, at least 10 unique footprints, at least 20 unique footprints, at least 30 unique footprints, etc.).

The layouts and footprints of FIGS. 10A-10F have been described in relation to bumps 72-B of FIGS. 5 and 6. However, any of the layouts and footprints of FIGS. 10A-10F may also apply to recesses 72-R of FIG. 7, structures 76-S of FIG. 8, and structures 76-S of FIG. 9.

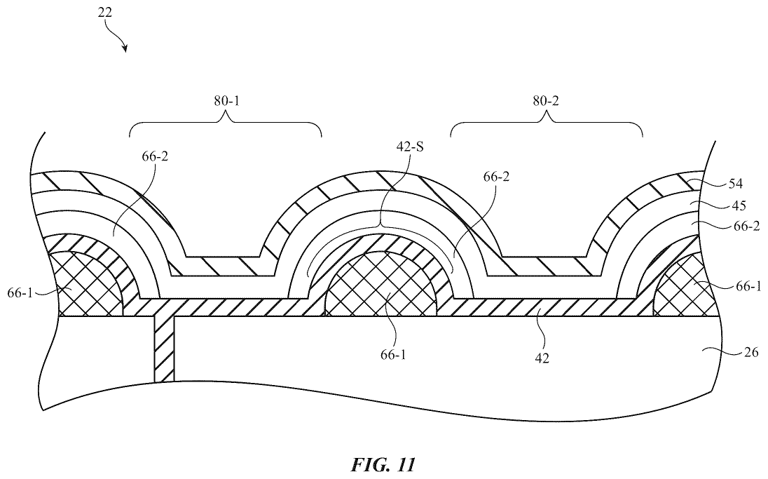

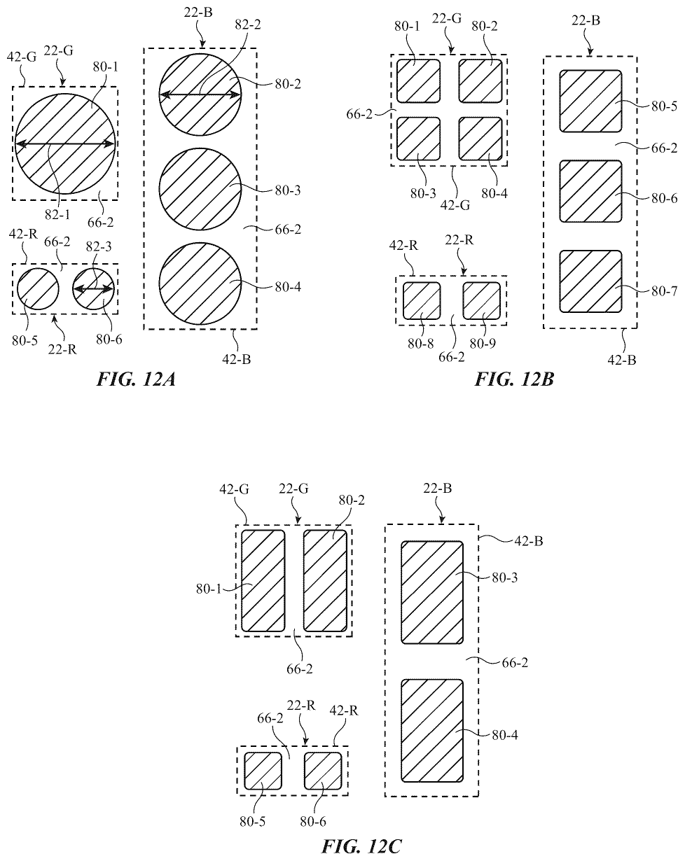

FIGS. 11 and 12 show an arrangement that may be used to improve efficiency in display pixel 22 (instead or in addition to any of the techniques of FIGS. 5-10). In the arrangement of FIGS. 11 and 12, a light-emitting pixel of a given color may include a plurality of discrete light-emitting apertures defined by discrete pixel definition layer openings. Each discrete pixel definition layer opening may have an optical side mirror formed from a portion of reflective anode metal.

FIG. 11 is a cross-sectional side view of an illustrative pixel with two discrete pixel definition layer openings. A first pixel definition layer 66-1 (sometimes referred to as planarization layer 66-1, dielectric layer 66-1, etc.) is formed on the upper surface of substrate 26. The first pixel definition layer 66-1 may be formed on substrate 26 before the metal for anode 42. Anode 42 is subsequently deposited and conforms to pixel definition layer 66-1 and the exposed portions of substrate 26. Anode 42 therefore has planar portions that are in direct contact with substrate 26 and side mirror portions 42-S that conform to pixel definition layer 66-1. An additional pixel definition layer 66-2 is formed over side mirror portions 42-S. Side mirror portions 42-S are interposed between pixel definition layers 66-1 and 66-2. Pixel definition layers 66-1 and 66-2 may sometimes be referred to as first and second portions of a pixel definition layer.

The additional pixel definition layer 66-2 defines multiple light-emitting openings for the pixel. In the example of FIG. 11, pixel definition layer 66-2 defines a first light-emitting aperture 80-1 and a second light-emitting aperture 80-2. The same OLED layers 45 are included in both light-emitting apertures 80-1 and 80-2. Additionally, light-emitting apertures 80-1 and 80-2 are both controlled by a common anode 42. The light-emitting apertures 80-1 and 80-2 emit light of the same color and same luminance and are therefore effectively a part of the same pixel 22. However, including multiple discrete openings with an intervening optical side mirror as in FIG. 11 may improve efficiency of the pixel.

FIGS. 12A, 12B, and 12C are top views of illustrative pixels with multiple light-emitting openings. In FIGS. 12A-12C, the cross-hatched areas represent the footprint of the light-emitting apertures 80. The dashed outlines represent the footprints of anodes 42. The white space surrounding each opening 80 represents the footprint of pixel definition layer 66-2 (and, approximately, side mirror portions 42-S and pixel definition layer 66-1). FIG. 12A shows a green pixel 22-G with one pixel definition layer opening 80-1, a blue pixel 22-B with three pixel definition layer openings 80-2, 80-3, and 80-4, and a red pixel with two pixel definition layer openings 80-5 and 80-6. The green pixel 22-G has a respective anode 42-G. The blue pixel 22-B has a respective anode 42-B. The red pixel 22-R has a respective anode 42-R. FIG. 12A therefore demonstrates how, within a single display, some pixels may have one pixel definition layer opening, some pixels may have two pixel definition layer openings, some pixels may have three pixel definition layer openings, etc.

In FIG. 12A, each pixel definition layer opening has a circular footprint. The opening for the green pixel has a diameter 82-1, each opening for the blue pixel has a diameter 82-2, and each opening for the red pixel has a diameter 82-3. Diameters 82-1, 82-2, and 82-3 may be different. As one example, diameter 82-1 may be greater than diameter 82-2 and diameter 82-2 may be greater than 82-3.

The example in FIG. 12A of the pixel definition layer openings having circular footprints is merely illustrative. In another possible arrangement, shown in FIG. 12B, the pixel definition layer openings have square footprints. FIG. 12B shows a green pixel 22-G with four pixel definition layer openings 80-1, 80-2, 80-3, and 80-4 (e.g., in a 2×2 grid), a blue pixel 22-B with three pixel definition layer openings 80-5, 80-6, and 80-7, and a red pixel with two pixel definition layer openings 80-8 and 80-9. Each one of openings 80-1 through 80-9 has a square footprint. The square footprints of openings within each pixel may be the same size. However, the square footprints of openings between pixels of different colors may be different. For example, in FIG. 12B the blue pixel has the largest openings and the red pixel has the smallest openings.

In another possible arrangement, shown in FIG. 12C, one or more pixel definition layer openings may have rectangular footprints. FIG. 12C shows a green pixel 22-G with two non-square rectangular pixel definition layer openings 80-1 and 80-2, a blue pixel 22-B with two non-square rectangular pixel definition layer openings 80-3 and 80-4, and a red pixel with two square pixel definition layer openings 80-5 and 80-6.

The non-square rectangular footprints of FIG. 12C may have any desired aspect ratio (e.g., at least 3:2, at least 2:1, at least 3:1, at least 5:1, etc.). The direction of the longer side of the non-square rectangle may be aligned in a target direction relative to the electronic device to improve off-axis luminance along that axis.

In general, each opening 80 may have a footprint of any desired shape (e.g., square, circular, oval, non-square rectangular, etc.). A single pixel may have any desired number of openings 80 (e.g., 1, 2, 3, 4, more than 4, etc.). Within a single pixel, each opening may have the same shape or different openings may have different shapes.

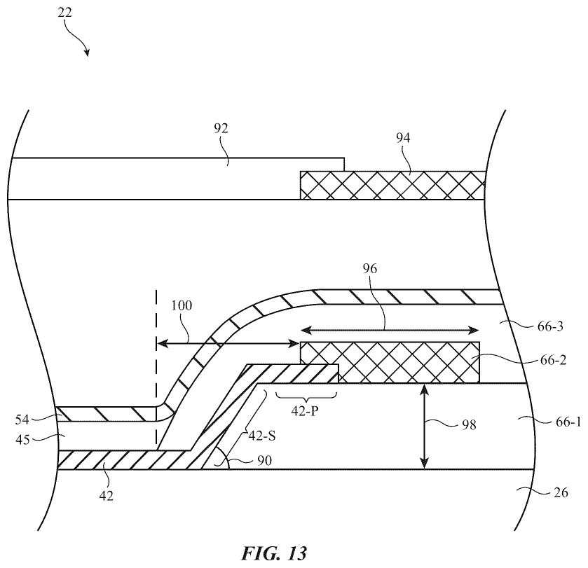

It may be desirable to incorporate a light absorbing pixel definition layer into pixel 22 to mitigate artifacts. As one example, a display pixel 22 may include a color filter element 92 and an opaque masking layer 94. FIGS. 13-15 show cross-sectional side views of display pixels with color filter elements and opaque masking layers.

In each one of FIGS. 13-15, the color filter element may pass light of a given color that is emitted by the display pixel and blocks light of other colors. As examples, when pixel 22 is a red pixel the color filter element 92 transmits red light and blocks green and blue light, when pixel 22 is a blue pixel the color filter element 92 transmits blue light and blocks green and red light, when pixel 22 is a green pixel the color filter element 92 transmits green light and blocks red and blue light.

In each one of FIGS. 13-15, opaque masking layer 94 may have a low transmittance of visible light (e.g., less than 30%, less than 20%, less than 10%, less than 5%, less than 3%, less than 1%, etc.). Opaque masking layer 94 may be formed from black ink or another desired material.

There may optionally be a circular polarizer that overlaps display pixel 22 to mitigate reflections of ambient light by display pixel 22. Circular polarizers suppress reflections of ambient light but also mitigate the brightness of the light emitted by display pixel 22. The circular polarizer may therefore optionally be omitted (as shown in the example of FIGS. 13-15) to improve brightness and/or efficiency. When the circular polarizer is omitted, it may be desirable to incorporate a light absorbing pixel definition layer into display pixel 22 to mitigate reflections of ambient light by display pixel 22.

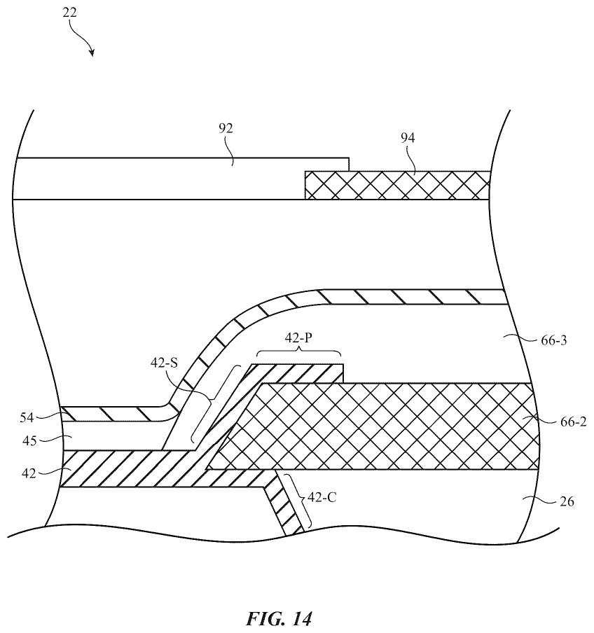

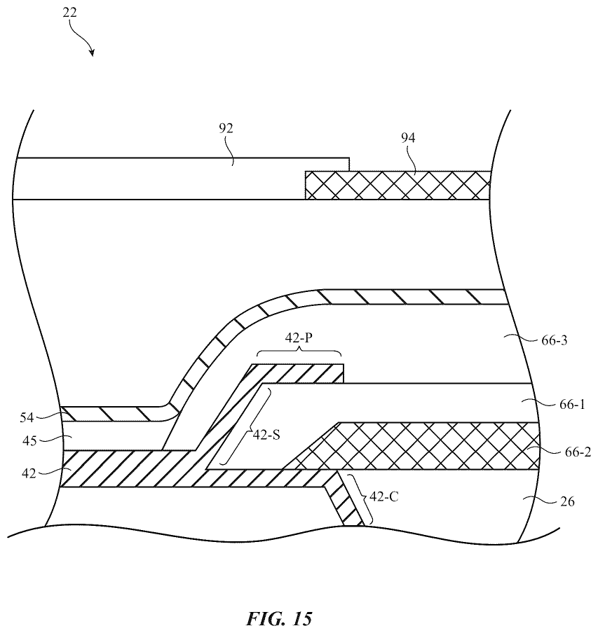

There are several ways to incorporate the light absorbing pixel definition layer into display pixel 22. FIG. 13 shows an example where a light absorbing pixel definition layer is formed above the metal of an anode side mirror portion and FIGS. 14 and 15 show examples where a light absorbing pixel definition layer is formed below the metal of an anode side mirror portion.

As shown in FIG. 13, a first pixel definition layer 66-1 (sometimes referred to as planarization layer 66-1, dielectric layer 66-1, etc.) is formed on substrate 26. The first pixel definition layer 66-1 may define a tapered surface for side mirror portion 42-S of anode 42 (similar to as shown and discussed in connection with FIG. 6). Pixel definition layer 66-1 may have a high transparency (e.g., greater than 60%, greater than 70%, greater than 80%, greater than 90%, greater than 95%, between 60% and 99%, etc.). A portion 42-P of the anode overlaps a planar top surface of pixel definition layer 66-1. In FIG. 13, pixel definition layer 66-2 overlaps portion 42-P and conforms to the edge of portion 42-P. Pixel definition layer 66-2 may have a low transparency (e.g., less than 30%, less than 20%, less than 10%, less than 5%, less than 3%, less than 1%, etc.). Pixel definition layer 66-2 may have a high absorption of incident visible light (e.g., greater than 60%, greater than 70%, greater than 80%, greater than 90%, greater than 95%, between 60% and 99%, etc.). Pixel definition layer 66-2 (sometimes referred to as black pixel definition layer 66-2, dielectric layer 66-2, etc.) may mitigate undesired reflections of ambient light by display pixel 22. Finally, a third pixel definition layer 66-3 (sometimes referred to as dielectric layer 66-3) is formed over anode side mirror portion 42-S, black pixel definition layer 66-2, and pixel definition layer 66-1. Pixel definition layer 66-3 may have a high transparency (e.g., greater than 60%, greater than 70%, greater than 80%, greater than 90%, greater than 95%, between 60% and 99%, etc.). Pixel definition layers 66-1 and 66-3 may optionally be formed from the same material.

In the example of FIG. 13, black pixel definition layer 66-2 has a width 96. Width 96 may be greater than 5 microns, greater than 10 microns, greater than 12 microns, greater than 14 microns, greater than 20 microns, between 10 and 20 microns, etc. Pixel definition layer 66-1 has a height 98. Height 98 may be less than 5 microns, less than 3 microns, greater than 1 micron, between 2 and 3 microns, etc. There may be a distance 100 between the centermost edge of pixel definition layer 66-3 (which defines the light emitting area of the pixel) and the centermost edge of black pixel definition layer 66-2. Distance 100 may be less than 10 microns, less than 5 microns, less than 3 microns, greater than 1 micron, between 3 and 10 microns, etc. Width 96 may be greater than distance 100 (e.g., by at least 5 microns, by at least a factor of 2, etc.). Pixel definition layer 66-1 may define a taper angle 90 that is less than 80 degrees, less than 70 degrees, less than 60 degrees, less than 50 degrees, less than 40 degrees, less than 30 degrees, less than 20 degrees, greater than 20 degrees, greater than 40 degrees, greater than 60 degrees, greater than 70 degrees, between 10 degrees and 80 degrees, between 50 degrees and 70 degrees, etc.

FIG. 14 shows an alternate arrangement where black pixel definition layer 66-2 is formed below anode side mirror portion 42-S. As shown in FIG. 14, black pixel definition layer 66-2 may define a tapered surface for side mirror portion 42-S of anode 42 (similar to as shown and discussed in connection with FIG. 6). Pixel definition layer 66-3 is formed over anode side mirror portion 42-S and black pixel definition layer 66-2. FIG. 14 also shows an anode contact portion 42-C (e.g., that may provide a control signal to the anode from display driver circuitry 20A within display 14). As shown, the anode contact may be formed under the black pixel definition layer.

Pixel definition layer 66-2 may have a low transparency (e.g., less than 30%, less than 20%, less than 10%, less than 5%, less than 3%, less than 1%, etc.). Pixel definition layer 66-2 may have a high absorption of incident visible light (e.g., greater than 60%, greater than 70%, greater than 80%, greater than 90%, greater than 95%, between 60% and 99%, etc.). Pixel definition layer 66-3 may have a high transparency (e.g., greater than 60%, greater than 70%, greater than 80%, greater than 90%, greater than 95%, between 60% and 99%, etc.).

Pixel definition layer 66-2 in FIG. 14 may define a taper angle 90 that is less than 80 degrees, less than 70 degrees, less than 60 degrees, less than 50 degrees, less than 40 degrees, less than 30 degrees, less than 20 degrees, greater than 20 degrees, greater than 40 degrees, greater than 60 degrees, greater than 70 degrees, between 10 degrees and 80 degrees, between 50 degrees and 70 degrees, etc.

The arrangement of FIG. 15 is similar to the arrangement of FIG. 13, except black pixel definition layer 66-2 is moved below pixel definition layer 66-1 in FIG. 15. Pixel definition layer 66-1 therefore defines a tapered surface for side mirror portion 42-S of anode 42 (similar to as shown and discussed in connection with FIG. 13). Pixel definition layer 66-1 overlaps a black pixel definition layer 66-2 that is formed on the upper surface of substrate 26. Pixel definition layer 66-3 is formed over anode side mirror portion 42-S and pixel definition layers 66-1 and 66-2. Pixel definition layer 66-3 directly contacts pixel definition layer 66-1 in FIG. 15. FIG. 15 also shows an anode contact portion 42-C (e.g., that may provide a control signal to the anode from display driver circuitry 20A within display 14). As shown, the anode contact may be formed under the black pixel definition layer. With the arrangement of FIG. 15, pixel definition layer 66-1 is used to control the taper angle of side mirror 42-S (instead of black pixel definition layer 66-2 as in FIG. 14), which may mitigate manufacturing cost and complexity.

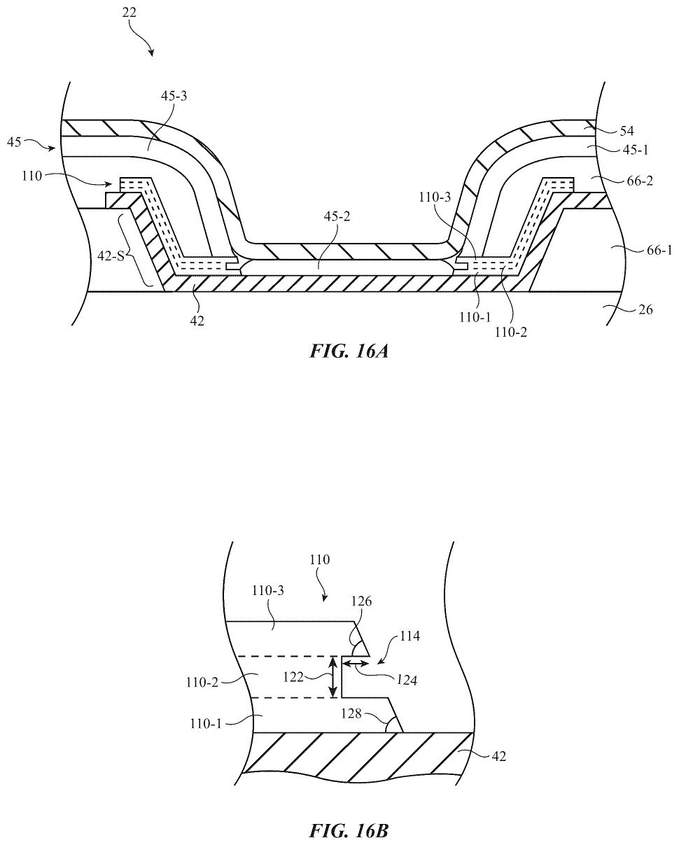

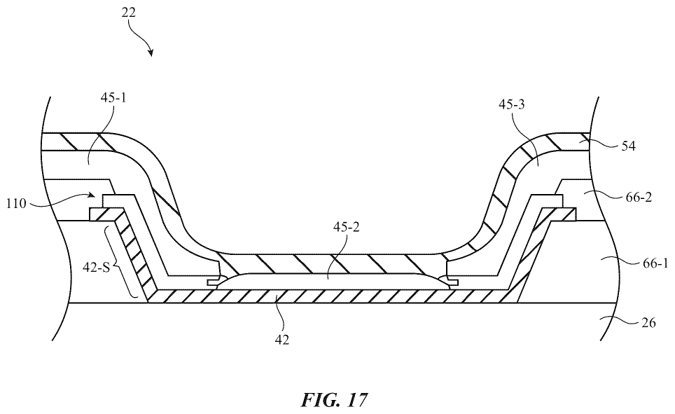

Any of the display pixels described herein may optionally include a cutting structure. FIGS. 16 and 17 are cross-sectional side views of display pixels with cutting structures 110. The cutting structures 110 may cause one or more discontinuities in one or more of the layers in OLED layers 45. Without discontinuities in OLED layers 45, lateral leakage may cause crosstalk between the pixels. For example, when a given pixel is on and an adjacent pixel is nominally off, leakage current may pass through the conductive OLED layers to the adjacent pixel and cause undesired emission of light from the nominally off adjacent pixel.

As will be shown and discussed in more detail in connection with FIGS. 16 and 17, the cutting structures 110 may have an undercut that causes a discontinuity in OLED layers 45 during the deposition of the OLED layers 45. The discontinuity in the OLED layers results in mitigated leakage current between adjacent pixels. FIGS. 16A and 17 show pixels 22 with cutting structures 110. FIG. 16B shows a detailed view of cutting structure 110.

In the example of FIGS. 16A and 16B, cutting structure 110 may be formed from portions 110-1, 110-2, and 110-3 (sometimes referred to as layers 110-1, 110-2, and 110-3). Portions 110-1, 110-2, and 110-3 may optionally be formed during individual deposition steps. Each portion may be formed from any desired material. In one illustrative arrangement, portions 110-1 and 110-3 may be formed from the same material (e.g., silicon dioxide) whereas portion 110-2 is formed from a different material (e.g., silicon nitride).

Each one of portions 110-1, 110-2, and 110-3 may have a thickness that is equal to any desired distance (e.g., less than 1 micron, less than 500 nanometers, less than 250 nanometers, less than 150 nanometers, less than 100 nanometers, less than 75 nanometers, less than 50 nanometers, less than 35 nanometers, less than 25 nanometers, less than 20 nanometers, more than 10 nanometers, more than 20 nanometers, between 10 and 100 nanometers, etc.). The thicknesses may be the same or may be different.

As shown in FIG. 16B, cutting structure 110 has an undercut 114 (sometimes referred to as a recess, cavity, hole, indentation, etc.). The undercut is a void in the cutting structure material that is still covered by a portion of the cutting structure. As shown in FIG. 16B, the undercut may have a width 124 and a height 122. In this arrangement, width 124 is defined as the distance between the edge of portion 110-3 of the cutting structure and the edge of portion 110-2 of the cutting structure. Height 122 is defined as the distance between a lower surface of portion 110-3 of the cutting structure and an upper surface of portion 110-1 of the cutting structure. Width 124 and height 122 may each be any desired distance (e.g., less than 5 microns, less than 1 micron, less than 500 nanometers, less than 250 nanometers, less than 150 nanometers, less than 100 nanometers, less than 75 nanometers, less than 50 nanometers, less than 35 nanometers, less than 25 nanometers, less than 20 nanometers, more than 10 nanometers, more than 20 nanometers, between 10 and 100 nanometers, etc.). Height 122 and width 124 may be the same or may be different. In one example, height 122 may be less than 50 nanometers and width 124 may be greater than 20 nanometers.

The angles of the edges of portions 110-1, 110-2, and 110-3 may be selected to control the discontinuities of the overlying organic light-emitting diode layers. As shown in FIG. 16B, portion 110-1 has an edge surface that is at an angle 128 relative to the planar upper surface of anode 42 (and relative to the planar lower surface of portion 110-1). Portion 110-3 has an edge surface that is at an angle 126 relative to the planar upper surface of anode 42 (and relative to the planar lower surface of portion 110-3). Angles 126 and 128 may be the same or may be different. Each of the angles may be any desired angle (e.g., between 45° and 90°, between 25° and 135°, between 45° and 55°, between 55° and 65°, between 75° and 85°, between 85° and 95° between 45° and 65°, between 70° and 90°, between 10° and 45°, less than 90°, etc.).

In FIG. 16B, a portion of layer 110-1 is not covered by layer 110-3. Said another way, layer 110-1 extends past the edge of layer 110-3 (e.g., towards the center of the anode). The width of the portion of layer 110-1 that is not covered by layer 110-3 may be any desired distance (e.g., less than 5 microns, less than 1 micron, less than 500 nanometers, less than 250 nanometers, less than 150 nanometers, less than 100 nanometers, less than 75 nanometers, less than 50 nanometers, less than 35 nanometers, less than 25 nanometers, less than 20 nanometers, less than 10 nanometers, more than 10 nanometers, more than 20 nanometers, between 10 and 100 nanometers, greater than 40 nanometers, etc.). The portion of layer 110-1 that is not covered by layer 110-3 may be referred to as a step portion of the cutting structure.

Of the OLED layers 45, the hole injection layer may be highly susceptible to lateral leakage. Therefore, the undercut 114 of FIG. 16B may have dimensions selected to cause a discontinuity in at least the hole injection layer of the OLED layers 45.

Returning to FIG. 16A, cutting structures 110 may create one or more discontinuities between a portion 45-2 of OLED layers 45 in a light-emitting area of pixel 22 and portions 45-1 and 45-2 of OLED layers 45 outside of the light-emitting area of pixel 22. Cathode 54 may not have any discontinuities or a separate electrical connection may be provided between cathode portions to ensure a uniform common cathode voltage cross the display.

When pixel 22 includes a cutting structure 110 and an anode side mirror portion 42-S, the cutting structure 110 may be overlapped by pixel definition layer portion 66-2. In FIG. 16A, pixel definition layer 66-1 defines a tapered surface that is overlapped by side mirror portion 42-S. Cutting structure 110 overlaps side mirror portion 42-S and the tapered surface of pixel definition layer 66-1. Pixel definition layer 66-2 overlaps cutting structure 110, side mirror portion 42-S, and the tapered surface of pixel definition layer 66-1.

In an alternate arrangement, shown in FIG. 17, pixel definition layer 66-1 defines a tapered surface that is overlapped by side mirror portion 42-S. Cutting structure 110 overlaps side mirror portion 42-S and the tapered surface of pixel definition layer 66-1. Pixel definition layer 66-2 overlaps the edges of cutting structure 110 and side mirror portion 42-S. However, pixel definition layer 66-2 does not overlap the tapered surface of pixel definition layer 66-1. Instead, portions 45-1 and 45-3 of OLED layers 45 are in direct contact with cutting structures 110 over the tapered surface.

In yet another possible arrangement, pixel definition layer 66-2 may be omitted entirely and cutting structure 110 may extend across the entire area between adjacent pixels (and therefore serves as a pixel definition layer for the display pixels).

In general, pixels 22 in a single display 14 may have any of the arrangements shown and described herein. Pixels of different colors may have different arrangements (e.g., all of the red pixels have a first arrangement, all of the blue pixels have a second arrangement, and all of the green pixels have a third arrangement) or pixels of the same color may have different arrangements (e.g., some of the red pixels have a first arrangement and some of the red pixels have a second arrangement).

In the arrangements described herein thus far, a single layer of material 72 is used to define bumps 72-B or recesses 72-R. With this type of arrangement, a single layer of material may be deposited and patterned (e.g., via wet etching or dry etching) to form desired cross-sectional shapes. As previously discussed, the single layer of material 72 may be the same material as planarization layer 74 in FIG. 6. Alternatively, layer 72 may be formed from a different material than planarization layer 74. Layer 72 may be formed from silicon dioxide or any other desired material.

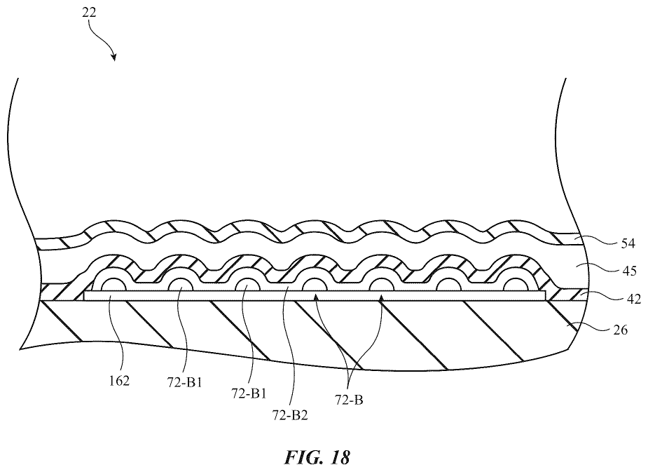

In another possible arrangement, multiple layers of materials may be used to define bumps 72-B. FIG. 18 shows a cross-sectional side view of a display pixel with multilayer bumps. As shown in FIG. 18, there may be a plurality of discrete bumps 72-B1 formed from a common layer of material. The common layer of material may be silicon dioxide or any other desired material. The multilayer bumps 72-B also include an additional layer 72-B2 that is formed continuously across bumps 72-B1. Additional layer 72-B2 may be the same material (and deposited in the same manufacturing step) as planarization layer 74 in FIG. 6. Bumps 72-B are therefore formed from both bumps 72-B1 and continuous overlying layer 72-B2.

In any of the embodiments described herein, an adhesion layer 162 may be incorporated between substrate 26 and bumps 72-B (or recesses 72-R, structured layer 76, etc.). The adhesion layer may improve adhesion between bumps 72-B and substrate 26 (compared to when bumps 72-B are formed directly on substrate 26). The adhesion layer may be formed from any desired material (e.g., silicon dioxide, silicon nitride, etc.).

The foregoing is merely illustrative and various modifications can be made by those skilled in the art without departing from the scope and spirit of the described embodiments. The foregoing embodiments may be implemented individually or in any combination.

What is claimed is:

1. An electronic device comprising a display that includes an array of pixels, wherein a pixel in the array of pixels comprises:
a substrate;
a layer of material on the substrate that defines a plurality of features;
an anode that conforms to the plurality of features, wherein the anode has a plurality of curved portions that is aligned with the plurality of features;
organic light-emitting diode layers that overlap the anode; and
a cathode that overlaps the organic light-emitting diode layers.

2. The electronic device defined in claim 1, wherein the plurality of features comprises a plurality of bumps.

3. The electronic device defined in claim 1, wherein the plurality of features comprises a plurality of recesses.

4. The electronic device defined in claim 1, wherein each feature in the plurality of features has a height and a width, wherein the height is less than 3 microns, and wherein the width is less than 5 microns.

5. The electronic device defined in claim 1, wherein the plurality of features is arranged in a regular grid of rows and columns.

6. The electronic device defined in claim 1, wherein the plurality of features comprises footprints that define concentric rings.

7. The electronic device defined in claim 1, further comprising:
a first layer that defines a tapered surface, wherein a portion of the anode overlaps and conforms to the tapered surface; and
a pixel definition layer that defines a light-emitting aperture for the pixel, wherein the pixel definition layer overlaps the portion of the anode.

8. The electronic device defined in claim 7, further comprising:
a black pixel definition layer that is interposed between the first layer and the pixel definition layer.

9. The electronic device defined in claim 7, wherein the first layer is a black pixel definition layer.

10. The electronic device defined in claim 7, further comprising:
a black pixel definition layer that is interposed between the first layer and the substrate.

11. The electronic device defined in claim 7, wherein the layer of material and the first layer are formed from a same material.

12. The electronic device defined in claim 7, further comprising:
a cutting structure that causes at least one discontinuity in at least one of the organic light-emitting diode layers, wherein the cutting structure overlaps and conforms to the portion of the anode.

13. The electronic device defined in claim 7, wherein the pixel definition layer is a cutting structure that causes at least one discontinuity in at least one of the organic light-emitting diode layers.

14. The electronic device defined in claim 1, wherein the pixel further comprises:
a first passivation layer that overlaps the cathode;
a planarization layer that overlaps the first passivation layer;
a second passivation layer that overlaps the planarization layer; and
a color filter element that overlaps the second passivation layer, wherein the planarization layer has a thickness that is less than 3 microns.

15. The electronic device defined in claim 1, wherein the plurality of features comprises a plurality of bumps defined by a first layer formed from a first material and a second layer formed from a second material that is different than the first material.

16. An electronic device comprising a display that includes an array of pixels, wherein a pixel in the array of pixels comprises:
a substrate;
an anode with a footprint;
organic light-emitting diode layers that overlap the anode;
a cathode that overlaps the organic light-emitting diode layers; and
a pixel definition layer that defines multiple light-emitting apertures for the pixel, wherein each one of the multiple light-emitting apertures overlaps the footprint and wherein the anode overlaps the pixel definition layer between the multiple light-emitting apertures.

17. The electronic device defined in claim 16, wherein the pixel definition layer comprises a first portion that is formed between the substrate and the anode and a second portion that overlaps the first portion and wherein the anode is interposed between the first and second portions of the pixel definition layer.

18. The electronic device defined in claim 16, wherein the multiple light-emitting apertures comprise non-square rectangular footprints.

19. The electronic device defined in claim 16, wherein the multiple light-emitting apertures comprise circular footprints.

20. An electronic device comprising a display that includes an array of pixels, wherein a pixel in the array of pixels comprises:
a substrate;
an anode that has a first portion on the substrate, a second portion, and a conductive via between the first and second portions, wherein the first portion is more reflective than the second portion;
a layer of material on the first portion of the anode that defines a plurality of structures, wherein the plurality of structures is interposed between the first and second portions of the anode;
an additional material that is interposed between the first and second portions of the anode and that conforms to the plurality of structures, wherein the additional material has a different refractive index than the layer of material;
organic light-emitting diode layers that overlap the second portion of the anode; and
a cathode that overlaps the organic light-emitting diode layers.

21. The electronic device defined in claim 20, wherein the plurality of structures is arranged in rows and columns.

22. The electronic device defined in claim 20, wherein the layer of material comprises a conductive material.
